(19) United States
(12) Patent Application Publication
(10) Pub. No.: US 2015/0090318 A1
(43) Pub. Date: Apr. 2, 2015

(54) NOVEL FILM FOR SOLAR CELLS

(71) Applicants: Wilhelm Laufer, Ellerstadt (DE); Armin Eckert, Oberhausen-Rheinhausen (DE)

(72) Inventors: Wilhelm Laufer, Ellerstadt (DE); Armin Eckert, Oberhausen-Rheinhausen (DE)

(73) Assignee: Rhein Chemie Rheinau GmbH, Mannheim (DE)

(21) Appl. No.: 14/237,918

(22) PCT Filed: Aug. 20, 2012
(86) PCT No.: PCT/EP2012/066201

§ 371 Date: Oct. 31, 2014

(30) Foreign Application Priority Data
Aug. 22, 2011 (EP) 11178233.0

(51) Int. Cl. H01L 31/048; C08J 5/18

(52) U.S. Cl. CPC H01L 31/0481; C08J 5/18; C08J 2367/02; C08J 2379/00
USPC 136/251; 525/418

(57) ABSTRACT

The present invention relates to novel foils for solar cells which feature improved hydrolysis resistance, and to the solar cells comprising said foils.

The present invention relates to novel foils for solar cells which feature improved hydrolysis resistance, and to the solar cells comprising said foils.

After the decision that Germany is to abandon nuclear energy, there has been an upswing in photovoltaic generation of electricity.

As is known, photovoltaic generation of electricity converts solar energy directly into electrical energy by means of a silicon cell semiconductor. However, the quality of this solar-cell element is reduced when it is brought into direct contact with the ambient air. The arrangement therefore generally has a solar-cell element between a sealing material and a transparent surface-protection material (mostly glass) and a reverse-side surface-protection material (a reverse-side foil by way of example made of a polyester resin, a fluororesin, or the like), in order to achieve a buffer effect and to prevent ingress of foreign bodies and especially ingress of moisture.

Fluororesins (plastics based on polyvinyl fluoride) are particularly suitable for this application sector because of their inertness, but these are so expensive to produce and often not available in sufficient quantity, and polyester resins susceptible to hydrolysis are therefore used as alternatives. Development work is therefore mainly aimed at preventing hydrolysis of the polyester resin layer.

Examples of materials used for this purpose are carbodiimides, see EP-A 2262000. Preference is given here especially to aliphatic carbodiimides, e.g. Carbodilite® LA-1 and Carbodilite® HMV-8CV. However, these have the disadvantage of acting as hydrolysis stabilizer only at high concentrations.

The object of the present invention therefore consisted in providing foils for solar cells based on polyester which do not have the disadvantages of the prior art and especially are hydrolysis-resistant.

Surprisingly, it has now been found that foils comprising at least one polyester and from 0.5 to 2.5% by weight of at least one polymeric aromatic carbodiimide based on 1,3,5-triisopropyl-2,4-diisocyanatobenzene with weight-average molar mass M_{w} from 10 000 to 30 000 g/mol do not have the disadvantages of the prior art.

The present invention therefore provides foils for solar cells, comprising at least one polyester and from 0.5 to 2.5% by weight, preferably from 1.0 to 2.0% by weight, of at least one polymeric carbodiimide based on 1,3,5-triisopropyl-2,4-diisocyanatobenzene with weight-average molar mass M_{w} from 10 000 to 30 000 g/mol, preferably from 15 000 to 25 000 g/mol, very particularly preferably from 17 000 to 22 000, based on the polyester.

The weight-average molar masses were determined by means of GPC (gel permeation chromatography), measured in tetrahydrofuran (THF) against polystyrene as standard.

In one embodiment of the present invention, the polyester involves polyethylene terephthalate (PET), polyethylene naphthalate (PEN), polybutylene terephthalate (PBT), polytrimethylene terephthalate (PTT), and/or polycyclohexanedimethanol terephthalate (PCT). Particular preference is given here to polyethylene terephthalate (PET) and polytrimethylene terephthalate (PTT).

In another embodiment of the invention, the polyester involves a mixture of polyesters. In this connection, preference is given to a mixture of polyethylene terephthalate (PET) and polyethylene naphthalate (PEN).

The polyesters involve commercially available substances which by way of example are obtainable from Invista, Novapet S. A., Lanxess Deutschland GmbH, Corterra Polymers (Shell Chemicals), or else Teijin DuPont.

For the purposes of the invention, the carbodiimides preferably involve aromatic carbodiimides based on 1,3,5-triisopropyl-2,4-diisocyanatobenzene with weight-average molar mass M_{w} from 20 000 to 30 000 g/mol. These are available commercially and are obtainable by way of example from Rhein Chemie Rheinau GmbH.

The foils of the invention can also comprise other additives, e.g. pigments, dyes, fillers, stabilizers, antioxidants, plasticizers, processing aids, crosslinking agents, etc.

The foil of the invention is preferably produced by the process below.

In one embodiment of the invention, the polymeric carbodiimide based on 1,3,5-triisopropyl-2,4-diisocyanatobenzene with weight-average molar mass M_{w} from 10 000 to 30 000 g/mol is incorporated at the desired concentration into the polyester by means of a kneader and/or extruder.

In another embodiment of the invention, the polymeric carbodiimide based on 1,3,5-triisopropyl-2,4-diisocyanatobenzene with weight-average molar mass M_{w} from 10 000 to 30 000 g/mol is incorporated in the form of a polyester-containing masterbatch into the polyester by means of a kneader and/or extruder. The concentration of the carbodiimide in the masterbatch here is preferably from 10-20% by weight.

Additives, pigments, dyes, fillers, stabilizers, antioxidants, plasticizers, processing aids, and crosslinking agents optionally used are preferably incorporated in a mixing step with the polymeric carbodiimide into the polyester. The sequence of addition of carboddimide and additive here can be selected as desired.

The foil is preferably produced via mixing of carbodiimide or carbodiimide masterbatch and polyester in the melt and subsequent melt extrusion process, see also EP-A 2262000.

The following equipment can be used for the melt extrusion process: single-screw, twin-screw, or multiscrew extruders, planetary-gear extruders, cascade extruders, continuously operating co-kneaders (Buss type), and batchwise-operating kneaders, e.g. Banbury type, and other assemblies conventionally used in the polymer industry.

The foils here can be produced with any desired thickness. However, preference is given to layer thicknesses of from 25 to 300 micrometers.

The present invention also provides the use of the foil of the invention in solar cells, where it is preferably used for sealing and thus for protection from environmental effects, e.g. moisture, and from ingress of foreign bodies.

The present invention also provides a solar-cell module comprising at least one foil of the invention.

Solar cells are generally composed of a plurality of layers of different materials, for example
the transparent front panel made of by way of example glass panels or transparent substrates, e.g. polycarbonate,
the silicon wafers laminated in encapsulating foils consisting generally in ethylene-vinyl acetate,
a reverse-side foil made of polyvinyl fluoride and/or polyester, and
an aluminum frame.

There are moreover also known solar cells which also have, between the transparent front panel and the silicon wafer, transparent polymer layers, e.g. made of α-olefin-vinyl acetate copolymers, with olefins, selected from ethene, propene, butene, pentene, hexene, heptene, and octene, as by way of example described in EP-A 2031662.

The foil of the invention is used in the present invention as reverse-side foil in solar cells. The foil here can be used in any of the solar cells known in the prior art.

The solar cell here is produced by the processes described in the prior art, starting from the standard processes for the production of silicon by way of casting processes, Bridgeman processes, EFG (edgedefined film-fed growth) processes, or the Czochralski process, and subsequent production of the Si wafers, and the assembly of the abovementioned layers of material on top of one another, where the foil of the invention is used instead of the reverse-side foil normally used. Lamination processes can also be used here to combine the individual layers of the solar cell with one another, see EP-A 2031662.

The scope of the invention includes any desired combination of any of the moiety definitions, indices, parameters, and explanations provided above and listed hereinafter in general terms or in preferred ranges, Le. also combinations between the respective ranges and preferred ranges.

The examples below serve to illustrate the invention, with no resultant limiting effect.

### INVENTIVE EXAMPLES

The Following Substances were Used in the Examples

PET=polyethylene terephthalate obtainable from Novapet, used in examples 1 and 3-7.

In example No. 2, the abovementioned PET was extruded once in a ZSK 25 laboratory twin-screw extruder from Werner & Pfleiderer before the measurement described below was made.

Stabaxol® 1 LF, bis-2,6-diisopropylphenylcarbodiimide, obtained from Rhein Chemie Rheinau GmbH, used in example 3.

A polymeric carbodiimide based on 1,3,5-triisopropyl-2,4-diisocyanatobenzene weight-average molar mass M_{w} 2000<M<5000 g/mol, used in example 4.

A polymeric carbodiimide based on 1,3,5-triisopropyl-2,4-diisocyanatobenzene with weight-average molar mass
M_{w} 17 000 g/mol, used in example 5 (inv.)
M_{w} 21 700 g/mol, used in example 6 (inv.)
M_{w} 38 000 g/mol, used in example 7 (comp.)
M_{w} 51 000 g/mol, used in example 8 (comp.).

Carbodilite® LA 1, a polymeric aliphatic carbodiimide based on dicyclohexylmethane 4,4-diisocyanate (H12MDI) with weight-average molar mass M_{w}>20 000 g/mol, from Nisshinbo Chemical Inc., used in example No. 9

Carbodilite® HMV-8 CA, a polymeric aliphatic carbodiimide based on dicyclohexylmethane 4,4-diisocyanate (H12MDI) with weight-average molar mass M_{w} of about 10 000 g/mol, from Nisshinbo Chemical Inc., used in example No. 10.

The carbodiitnides were incorporated into the PET by means of a ZSK 25 laboratory twin-screw extruder from Werner & Pfleiderer.

Table 1 shows the nature and quantity of the carbodiimide used, and also the results measured in relation to hydrolysis resistance.

The for measurement of tensile strain at break, F3 standard test specimens were produced in an Arburg Allrounder 320 S 150-500 injection-molding machine.

For the hydrolysis test, these standard F3 test specimens were stored in water vapor at a temperature of 120° C. for 24 hours, and their tensile strain at break was measured after 0 and 24 hours.

The weight-average molar masses were determined by means of GPC (gel permeation chromatography), measured in THF against polystyrene as standard. Measurement equipment from Thermo Scientific was used for this purpose.

The values stated in table 1 are obtained from the following calculation:

Tensile strain at break [%]=(Tensile strain at break after 24 hours/Tensile strain at break after 0 hours)×100

TABLE 1

| | Example No. | | | | | | | | | |
|---|---|---|---|---|---|---|---|---|---|---|
| | 1 | 2 | 3 | 4 | 5 | 6 | 7 | 8 | 9 | 10 |
| | comp. | comp. | comp. | comp. | inv. | inv. | comp. | comp. | comp. | comp. |
| Quantity of CDI | 0 | 0 | 1.5 | 1.5 | 1.5 | 1.5 | 1.5 | 1.5 | 1.5 | 1.5 |
| [%] | | | | | | | | | | |
| Tensile strain | 38 | 36 | 84 | 89 | 91 | 95 | 83 | 76 | 31 | 5 |
| at break [%] | | | | | | | | | | |

comp. = comparative example,
inv. = of the invention

It is apparent that the highest hydrolysis resistance can be achieved when 1,3,5-triisopropyl-2,4-diisocyanatobenzene is used with weight-average molar mass M_{w} 20 000 g/mol.

What is claimed is:

1. A foil comprising at least one polyester and from 1.0-2.0% by weight of at least one polymeric carbodiimide based on 1,3,5-triisopropyl-2,4-diisocyanatobenzene with weight-average molar mass M_{w} from 10 000 to 30 000 g/mol, based on the polyester.

2. The foil as claimed in claim 1, characterized in that the polyester involves polyethylene terephthalate (PET), polyethylene naphthalate (PEN), polybutylene terephthalate (PBT), polytrimethylene terephthalate (PTT), and/or polycyclohexanedimethanol terephthalate (PCT).

3. The foil as claimed in claim 1 or 2, characterized in that the weight-average molar mass M_{w} is from 15 000 to 25 000 g/mol.

4. The foil as claimed in one or more of claims 1 to 3, characterized in that the weight-average molar mass M_{w} of the carbodiimide is from 17 000 to 22 000 g/mol, particularly preferably from 17 000 to 21 700 g/mol.

5. A solar-cell module comprising at least one foil as claimed in one or more of claims 1 to 4.

6. The use of a foil as claimed in one or more of claims 1 to 4 for the sealing of the solar cell.
